(19) United States
(12) Patent Application Publication
(10) Pub. No.: US 2025/0202493 A1
(43) Pub. Date: Jun. 19, 2025

(54) CONVERTER WITH IMPROVED SIGNAL-TO-NOISE RATIO AND METHOD OF OPERATION OF THE SAME

(71) Applicant: SAMSUNG ELECTRONICS CO., LTD., Suwon-si (KR)

(72) Inventors: Hojin Kim, Suwon-si (KR); Kent Edrian Lozada, Daejeon-si (KR); Donghun Lee, Suwon-si (KR); Seungtak Ryu, Daejeon-si (KR); Heewook Shin, Suwon-si (KR); Youngjae Cho, Suwon-si (KR); Michael Choi, Suwon-si (KR)

(73) Assignee: Korea Advanced Institute of Science and Technology, Daejeon (KR)

(21) Appl. No.: 18/974,398

(22) Filed: Dec. 9, 2024

(30) Foreign Application Priority Data
Dec. 13, 2023 (KR) 10-2023-0181165

(51) Int. Cl. H03M 1/08

(52) U.S. Cl. CPC H03M 1/0854

(57) ABSTRACT

An example converter includes a first adder, a first analog-to-digital converter, a second analog-to-digital converter, a digital noise coupling filter, and a digital filter. The first adder is configured to generate a differential analog signal corresponding to a difference between a first analog signal and a second analog signal. The first analog-to-digital converter is configured to convert the differential analog signal to a first digital signal. The second analog-to-digital converter is configured to convert a first quantization error corresponding to a difference between the differential analog signal and the first digital signal to a second digital signal. The digital noise coupling filter is configured to generate a second digital quantization signal corresponding to the second analog signal. The digital filter is configured to generate an output signal based on the first digital signal and the second digital signal.

### CROSS-REFERENCE TO RELATED APPLICATION

This application claims priority under 35 U.S.C. § 119 to Korean Patent Application No. 10-2023-0181165, filed on Dec. 13, 2023, in the Korean Intellectual Property office, the disclosure of which is incorporated by reference herein in its entirety.

### BACKGROUND

The demand for low-power, high-resolution converters for various electronic devices has continuously increased. In various electronic devices, it is generally considered important to meet high resolution and a dynamic range with more efficient power consumption than a conversion speed. High-order loop filters may be used to obtain high resolution.

As the sampling rate for an analog signal increases, a signal-to-noise ratio (SNR) may be improved, but as the sampling rate increases, the power consumption of the converter may increase. When the high-order loop filter is used, the stability of a circuit may be weakened and a maximum stable amplitude (MSA) may be reduced. Accordingly, an analog-to-digital converter, which can reduce noise without increasing the sampling rate and without using the high-order loop filter, is desired.

### SUMMARY

The present disclosure relates to a converter with an improved signal-to-noise ratio (SNR) by reducing the influence of quantization errors occurring in the analog-to-digital conversion process.

The issues to be solved by the technical idea of the present disclosure are not limited to the above-mentioned issues, and other issues not mentioned may be clearly understood by one of ordinary skill in the art from the following descriptions.

In some implementations, a converter includes a first adder configured to generate a third analog signal corresponding to a difference between a first analog signal, which corresponds to the input signal, and a second analog signal, a first analog-to-digital converter configured to convert the third analog signal to generate a first digital signal, a second analog-to-digital converter configured to convert a first quantization error corresponding to a difference between the third analog signal and the first digital signal to generate a second digital signal, a digital noise coupling filter configured to generate a second digital quantization signal corresponding to the second analog signal by performing a noise shaping operation on a first digital quantization signal corresponding to a second quantization error corresponding to a difference between the first quantization error and the second digital signal, and a digital filter configured to generate the output signal based on the first digital signal and the second digital signal.

In some implementations, a method of operation of a converter includes generating a third analog signal based on a difference between a first analog signal, which corresponds to the input signal, and a second analog signal, generating a first digital signal by converting the third analog signal, generating a second digital signal by converting a first quantization error corresponding to a difference between the third analog signal and the first digital signal, generating the second analog signal by performing a noise shaping operation on a digital signal based on a second quantization error corresponding to the difference between the first quantization error and the second quantization error, and generating the output signal based on the first digital signal and the second digital signal.

In some implementations, a converter includes a first adder configured to generate a differential signal based on a difference between the input signal and a feedback signal, a loop filter configured to perform a filtering operation on the differential signal based on a first transfer function corresponding to a low pass filter to generate a first analog signal, a main analog-to-digital converter configured to convert the first analog signal to generate a first digital signal and a second digital signal, a digital-to-analog converter configured to convert the first digital signal to generate a feedback signal to be fed back to the first adder, and a digital filter configured to generate the output signal, based on the first digital signal and the second digital signal, wherein the main analog-to-digital converter is configured to generate a third analog signal corresponding to a difference between the first analog signal and a second analog signal, convert the third analog signal to generate a first digital signal, and convert a first quantization error corresponding to a difference between the third analog signal and the first digital signal to generate the second digital signal.

### BRIEF DESCRIPTION OF THE DRAWINGS

Implementations will be more clearly understood from the following detailed description taken in conjunction with the accompanying drawings.

FIG. 1 is a diagram of an example of a converter.

FIG. 2 is an example diagram of a main analog-to-digital converter and a digital noise coupling filter.

FIG. 3 is a circuit diagram of an example of a main analog-to-digital converter.

FIGS. 4A, 4B, 4C, 4D, and 4E are circuit diagrams of operations of an example of a main analog-to-digital converter.

FIG. 5 is a diagram of an example of a digital filter.

FIG. 6 is a flowchart of an example of an operation of a converter.

FIG. 7 is a block diagram of an example of a communication device.

FIG. 8 is a block diagram of an example of a system-on-chip.

### DETAILED DESCRIPTION

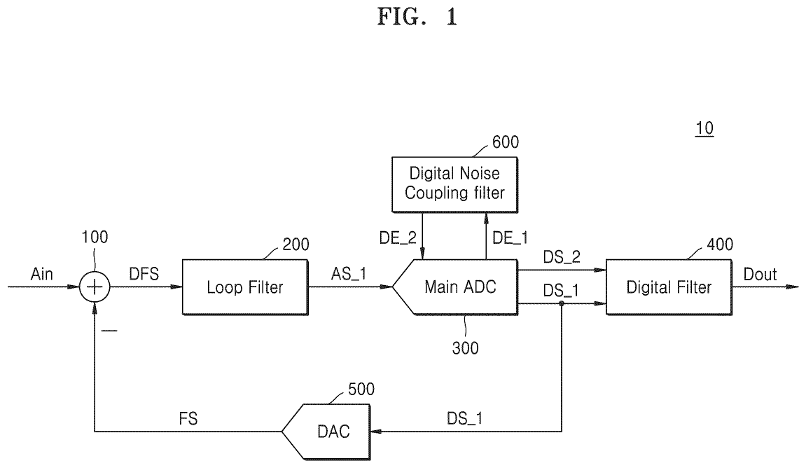

FIG. 1 is a diagram of an example of a converter 10.

Referring to FIG. 1, the converter 10 may convert an input signal Ain based on a plurality of reference voltages into an output signal Dout. In some implementations, the input signal Ain may be an analog signal, and the output signal Dout may be a digital signal including a plurality of bits.

The converter 10 may include a first adder 100, a loop filter 200, a main analog-to-digital converter (ADC) 300, a digital filter 400, a digital-analog converter (DAC) 500, and a digital noise coupling filter 600.

The first adder 100 may receive the input signal Ain from the outside. The first adder 100 may receive a feedback signal FS from the DAC 500. The first adder 100 may generate a differential signal DFS, based on the input signal Ain and the feedback signal FS. For example, the first adder 100 may generate the differential signal DFS, based on the input signal Ain and the feedback signal FS.

The loop filter 200 may receive the differential signal DFS from the first adder 100. The loop filter 200 may filter the differential signal DFS. For example, the loop filter 200 may remove or reduce signal components having a particular frequency among the signal components included in the differential signal DFS. For example, the loop filter 200 may include a configuration corresponding to a low pass filter. The loop filter 200 having a configuration corresponding to a low pass filter may remove or attenuate signal components having a frequency greater than or equal to a reference frequency included in the differential signal DFS. The loop filter 200 may generate a first analog signal AS_1 by filtering the differential signal DFS.

The loop filter 200 may generate the first analog signal AS_1 by filtering the differential signal DFS based on a first transfer function corresponding to the low pass filter. Hereinafter, although the loop filter 200 is described on the premise that the first analog signal AS_1 is generated by performing low pass filtering on the differential signal DFS, the loop filter 200 is not limited thereto.

The converter 10 may increase a signal-to-noise ratio (SNR) by reducing noise of the output signal Dout by increasing the order of the loop filter 200. However, when the order of the loop filter 200 is increased, the stability of the converter 10 may decrease, a maximum stable amplitude (MSA) may decrease, and power consumption may increase due to an increase in the order. The converter 10 may generate the output signal Dout with an improved SNR, based on a multi-stage noise shaping (MASH) structure, the digital noise coupling filter 600, and the digital filter 400, which are described below, without increasing the order of the loop filter 200. More detailed descriptions thereof are given below.

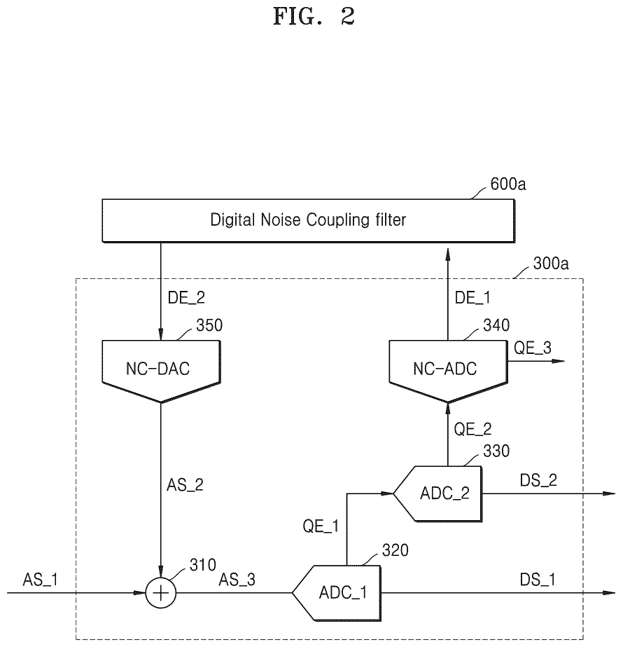

The main ADC 300 may receive the first analog signal AS_1 from the loop filter 200. The main ADC 300 may receive a second digital quantization signal DE_2 from the digital noise coupling filter 600. The main ADC 300 may generate a first digital signal DS_1 and a second digital signal DS_2 based on the first analog signal AS_1. The main ADC 300 may generate the first digital signal DS_1 based on a third analog signal (AS_3 in FIG. 2) corresponding to the difference between the first analog signal AS_1 and the second analog signal (AS_2 in FIG. 2) corresponding to the second digital quantization signal DE_2. In addition, the main ADC 300 may generate the second digital signal DS_2 based on the first quantization error (QE_1 in FIG. 2) corresponding to the difference between the third analog signal (AS_3 in FIG. 2) and the first digital signal DS_1. More detailed descriptions of the main ADC 300 are described below with reference to FIG. 2.

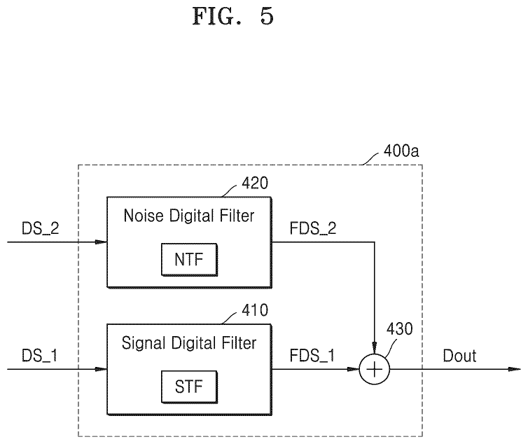

The digital filter 400 may receive the first digital signal DS_1 and the second digital signal DS_2 from the main ADC 300. The digital filter 400 may generate the output signal Dout, based on the first digital signal DS_1 and the second digital signal DS_2. For example, the digital filter 400 may generate a filtered second digital signal DS_2 by delaying the second digital signal DS_2 and may generate the output signal Dout by adding the filtered second digital signal DS_2 to the first digital signal DS_1. Because the main ADC 300 and the digital noise coupling filter 600 have a feedback structure, the filtered second digital signal DS_2 may be a signal before a cycle compared to the first digital signal DS_1. Accordingly, the digital filter 400 may generate the output signal Dout by adding the first digital signal DS_1 at a current time point to the second digital signal DS_2 filtered at a previous time point. More detailed descriptions of the digital filter 400 are described below with reference to FIG. 5.

The DAC 500 may receive the first digital signal DS_1 from the main ADC 300. The DAC 500 may convert the first digital signal DS_1 into the feedback signal FS.

As described above, the first adder 100 may generate the differential signal DFS corresponding to the input signal Ain and the feedback signal FS. In some implementations, the first adder 100 may generate the differential signal DFS by subtracting the feedback signal FS from the input signal Ain. As the DAC 500 converts the first digital signal DS_1 to continuously provide the feedback signal FS to the first adder 100, the difference between the input signal Ain and the first digital signal DS_1 may decrease. Accordingly, as the feedback signal FS based on the first digital signal DS_1 is fed back to the first adder 100 by the DAC 500, the converter 10 may accurately convert the input signal Ain into the output signal Dout.

The digital noise coupling filter 600 may receive a first digital quantization signal DE_1 from the main ADC 300. The digital noise coupling filter 600 may perform a noise shaping operation on the first digital quantization signal DE_1 to generate the second digital quantization signal DE_2. The first digital quantization signal DE_1 and the second digital quantization signal DE_2 may be digital signals represented by a plurality of bits. The main ADC 300 may convert a second quantization error (QE_2 in FIG. 2) corresponding to the difference between a first quantization error (QE_1 in FIG. 2) and the second digital signal DS_2 into the first digital quantization signal DE_1. The digital noise coupling filter 600 may perform the noise shaping operation on a digital signal.

Although the digital noise coupling filter 600 is described as performing the noise shaping operation on a digital signal for convenience of description in the present disclosure, the digital noise coupling filter 600 may not perform the noise shaping operation directly on the digital signal. When a digital signal (for example, DE_2) passing through the digital noise coupling filter 600 is fed back, the digital noise coupling filter 600 may cause a noise shaping effect to appear in the output signal Dout. In other words, the digital noise coupling filter 600 may cause the noise shaping to occur in the output signal Dout. Accordingly, in the present disclosure, that the digital noise coupling filter 600 performs a noise shaping operation on a digital signal may mean that a noise shaping effect appears in the output signal Dout based on the digital signal having passed through the digital noise coupling filter 600. This effect may also be applicable to the interpretation of the claims.

Noise shaping may mean signal processing for increasing the SNR by reducing noise in an in-band by changing the spectral shape of noise generated during the quantization process of a digital signal.

The digital noise coupling filter 600 may have lower complexity in circuit implementation and consume relatively less power than an analog noise coupling filter. In addition, the digital noise coupling filter 600 may be less sensitive to changes in process, voltage, and temperature (PVT). Thus, the converter 10 may generate the output signal Dout with relatively low power by including the digital noise coupling filter 600.

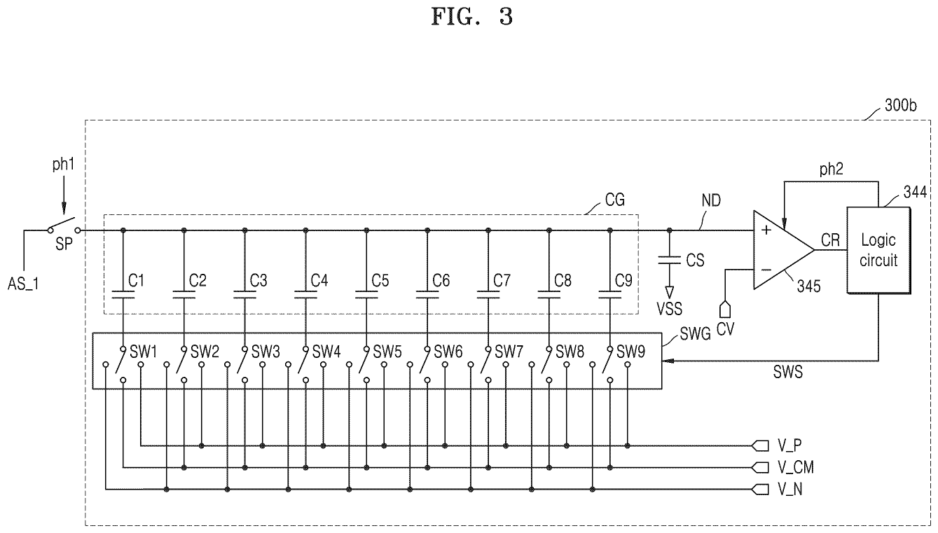

Although not illustrated in FIG. 1 for convenience of description, the main ADC 300 may further include a sampler (SP of FIG. 3). The sampler (SP in FIG. 3) may receive the first analog signal AS_1 from the loop filter 200. The sampler (SP in FIG. 3) may receive a sampling signal (ph1 in FIG. 3) from a logic circuit (344 in FIG. 3) included in the main ADC 300. The sampler (SP in FIG. 3) may sample the first analog signal AS_1 based on a frequency of the sampling signal (ph1 in FIG. 3). The sampled first analog signal AS_1 may include a non-continuous analog signal. Hereinafter, the first analog signal AS_1 is described below on the premise that the first analog signal AS_1 is an analog signal sampled by the sampler (SP in FIG. 3).

To improve the SNR of the output signal Dout, the frequency of the sampling signal (ph1 in FIG. 3) (hereinafter, referred to as a sampling ratio) may be increased. As the sampling ratio increases, the SNR of the output signal Dout may be improved, but power consumed for sampling may increase. The sampling ratio may be related to a successive approximation register (SAR) analog-to-digital converter (ADC), and the sampling ratio and the SAR ADC are described below with reference to FIG. 3. The converter 10 may generate the output signal Dout with an improved SNR, based on the MASH structure, the digital noise coupling filter 600, and the digital filter 400, which are included in the main ADC 300, without increasing the sampling ratio.

FIG. 2 is an example diagram of a main ADC 300a and a digital noise coupling filter 600a.

The main ADC 300a and the digital noise coupling filter 600a in FIG. 2 may respectively correspond to the main ADC 300 and the digital noise coupling filter 600 described above with reference to FIG. 1. Accordingly, duplicate descriptions given above with reference to FIG. 1 are omitted below.

Referring to FIG. 2, the main ADC 300a may include a second adder 310, a first ADC (ADC_1) 320, a second ADC (ADC_2) 330, a noise coupling (NC) ADC (NC-ADC) 340, and an NC-DAC 350.

The second adder 310 may receive the first analog signal AS_1 from the loop filter 200. As described above, the second adder 310 may receive a second analog signal AS_2 from the NC-DAC 350. The second adder 310 may generate the third analog signal AS_3, based on the first analog signal AS_1 and the second analog signal AS_2. For example, the second adder 310 may generate the third analog signal AS_3 based on the difference between the first analog signal AS_1 and the second analog signal AS_2.

The ADC_1 320 may receive the third analog signal AS_3 from the second adder 310. The ADC_1 320 may convert the third analog signal AS_3 into a first digital signal DS_1. The first digital signal DS_1 may be expressed in a plurality of bits. For example, the ADC_1 320 may convert the third analog signal AS_3 into a first digital signal DS_1 expressed in four bits.

The ADC_2 330 may receive a first quantization error QE_1 from the ADC_1 320. The first quantization error QE_1 may correspond to an error generated in a process in which the ADC_1 320 converts the third analog signal AS_3 into the first digital signal DS_1. In other words, the first quantization error QE_1 may correspond to the difference between the third analog signal AS_3 and the first digital signal DS_1. The ADC_2 330 may convert the first quantization error QE_1 into a second digital signal DS_2. The second digital signal DS_2 may be expressed in a plurality of bits. For example, the ADC_2 330 may convert the first quantization error QE_1 into a second digital signal DS_2 expressed in three bits.

The NC-ADC 340 according to the present disclosure may receive a second quantization error QE_2 from ADC_2 330. The second quantization error QE_2 may correspond to an error generated in a process in which the ADC_2 330 converts the first quantization error QE_1 into the second digital signal DS_2. In other words, the second quantization error QE_2 may correspond to the difference between the first quantization error QE_1 and the second digital signal DS_2. The NC-ADC 340 may convert the second quantization error QE_2 into a first digital quantization signal DE_1.

A third quantization error QE_3 may correspond to an error generated in the process of converting the second quantization error QE_2 into the first digital quantization signal DE_1 by the NC-ADC 340. In other words, the third quantization error QE_3 may correspond to the difference between the second quantization error QE_2 and the first digital quantization signal DE_1.

In the present disclosure, “receiving” each of the first quantization error QE_1, the second quantization error QE_2, and the third quantization error QE_3 is not limited to that the quantized error moves and is transferred between different members but may be a case in which a voltage level corresponding to the quantization error applied to a particular node by a certain operation of the converter (10 of FIG. 1) is used in the following operation.

The digital noise coupling filter 600a may receive a first digital quantization signal DE_1 from the main ADC 300a. The digital noise coupling filter 600a may receive the first digital quantization signal DE_1 from the NC-ADC 340. The digital noise coupling filter 600 may perform the filtering operation on the first digital quantization signal DE_1 to generate a second digital quantization signal DE_2. The second digital quantization signal DE_2 may be expressed in a plurality of bits. For example, the digital noise coupling filter 600a may perform the noise shaping operation on the first digital quantization signal DE_1 to generate a second digital quantization signal DE_2 represented in four bits. However, as described above, the digital noise coupling filter 600a may not directly perform the noise shaping operation, and the noise shaping effect may occur in the output signal Dout based on the second digital quantization signal DE_2.

The digital noise coupling filter 600a may perform the noise shaping operation on the first digital quantization signal DE_1 to generate a second digital quantization signal DE_2. In other words, the digital noise coupling filter 600a may attenuate components corresponding to a particular frequency among the components included in the first digital quantization signal DE_1. For example, the digital noise coupling filter 600a may be designed such that a signal corresponding to the digital quantization signal included in the output signal (Dout in FIG. 1) has high bandwidth pass characteristics.

The converter (10 in FIG. 1) may, by including the digital noise coupling filter 600a, obtain the noise shaping effect corresponding to a high order without increasing the order of the loop filter (200 in FIG. 1). The converter (10 in FIG. 1) according to the present disclosure may be less sensitive to PVT changes by including the digital noise coupling filter 600a instead of a noise coupling filter implemented in an analog manner. In addition, by including the digital noise coupling filter 600a, the converter (10 of FIG. 1) may include a low-order loop filter (200 in FIG. 1), and accordingly, the stability of the converter (10 of FIG. 1) may be improved and the maximum stable amplitude of the converter (10 of FIG. 1) may be increased, compared to the case of including a high-order loop filter. In addition, the converter (10 in FIG. 1) may be implemented in a simple structure, in which the ADC_1 320, the ADC_2 330, the NC-ADC 340, and the NC-DAC 350 share a comparator (345 in FIG. 3) and a logic circuit (344 in FIG. 3), as described below with reference to FIG. 3.

The NC-DAC 350 may receive the second digital quantization signal DE_2 from the digital noise coupling filter 600a. The NC-DAC 350 may convert the second digital quantization signal DE_2 into a second analog signal AS_2. The NC-DAC 350 may provide the second analog signal AS_2 to the second adder 310.

Referring to FIGS. 1 and 2, the converter 10 may include an M-N MASH structure. The M-N MASH structure may include the first adder 100, the loop filter 200, the ADC_1 320, the ADC_2 330, and the digital filter 400. M may be a positive integer and may mean an order of the loop filter 200 connected to an input terminal of the ADC_1 320. N may be a positive integer and may mean an order of a loop filter connected to an input terminal of the ADC_2 330. Referring to FIG. 2, because there is no loop filter connected to the input terminal of the ADC_2 330, the order may be 0, and accordingly, N may be 0. For example, the converter 10 may include the loop filter 200 having a low order, and thus, the converter 10 may have a 1-0 MASH structure. The converter 10 may, by including an M-0 MASH structure, generate the first digital signal DS_1 and the second digital signal DS_2. The converter 10 may, based on the digital filter 400, filter the second digital signal DS_2 corresponding to the first quantization error QE_1. The converter 10 may generate the output signal Dout obtained by removing or attenuating the first quantization error QE_1, based on the filtered second digital signal DS_2 and the first digital signal DS_1.

The quantization error QE_1 may decrease as the analog-to-digital conversion is repeated. Thus, according to the present disclosure, the size of the first quantization error QE_1 may be greater than the size of the second quantization error QE_2 and the size of the third quantization error QE_3. In addition, the size of the second quantization error QE_2 may be greater than the size of the third quantization error QE_3. As described above, the converter (10 of FIG. 1) may generate the output signal Dout in which a component corresponding to the first quantization error QE_1 is removed or attenuated based on the MASH structure, the digital noise coupling filter 600a, and the digital filter (400 in FIG. 1). The converter (10 of FIG. 1) may generate the output signal Dout with improved SNR by removing or attenuating a component corresponding to the first quantization error QE_1 corresponding to a relatively large error. More detailed descriptions related to this issue are given below.

FIG. 3 is a circuit diagram of an example of a main ADC 300b. FIG. 3 is a circuit diagram of the main ADC 300b implemented as a single SAR-ADC. However, a structure of the main ADC 300b is not limited to the structure illustrated in FIG. 3. For example, the main ADC 300b may further include a plurality of capacitors C1 through C9, a plurality of capacitors respectively symmetrical to a plurality of switches SW1 through SW9, and a plurality of switches, based on a reference node ND, for the stability of a converter operation.

An operation of each of the second adder 310, the ADC_1 320, the ADC_2 330, the NC-ADC 340, the NC-DAC 350, and the digital noise coupling filter 600a described above with reference to FIG. 2 may be performed based on a comparator control signal ph2, a switch control signal SWS, or the like provided by a logic circuit 344. For example, the ADC_1 (320 in FIG. 2) may generate the first digital signal (DS_1 in FIG. 2), based on the comparator control signal ph2 and the switch control signal SWS provided by the logic circuit 344, and may provide the first quantization error QE_1 to the ADC_2 (330 in FIG. 2).

The second adder 310, the ADC_1 320, the ADC_2 330, the NC-ADC 340, and the NC-DAC 350, which are included in the main ADC 300a of FIG. 2 are represented as distinct components for convenience of descriptions. However, the second adder 310, the ADC_1 320, the ADC_2 330, the NC-ADC 340, and the NC-DAC 350 are not limited thereto and as described below with reference to FIG. 3, may be implemented as a single SAR-ADC. In other words, the second adder (310 in FIG. 2), the ADC_1 (320 in FIG. 2), the ADC_2 (330 in FIG. 2), the NC-ADC (340 in FIG. 2), and the NC-DAC (350 in FIG. 2) may share one reference node ND, and each of them may share the logic circuit 344 and/or the comparator (345 in FIG. 3) to perform the operations described above.

Referring to FIG. 3, the main ADC 300b may include the logic circuit 344, the comparator 345, a capacitor group CG, a common capacitor CS, and a switch group SWG.

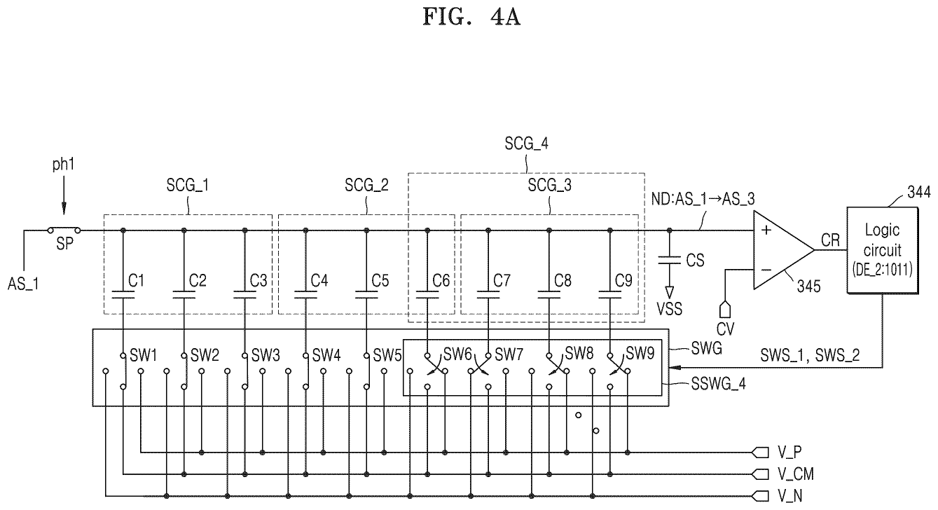

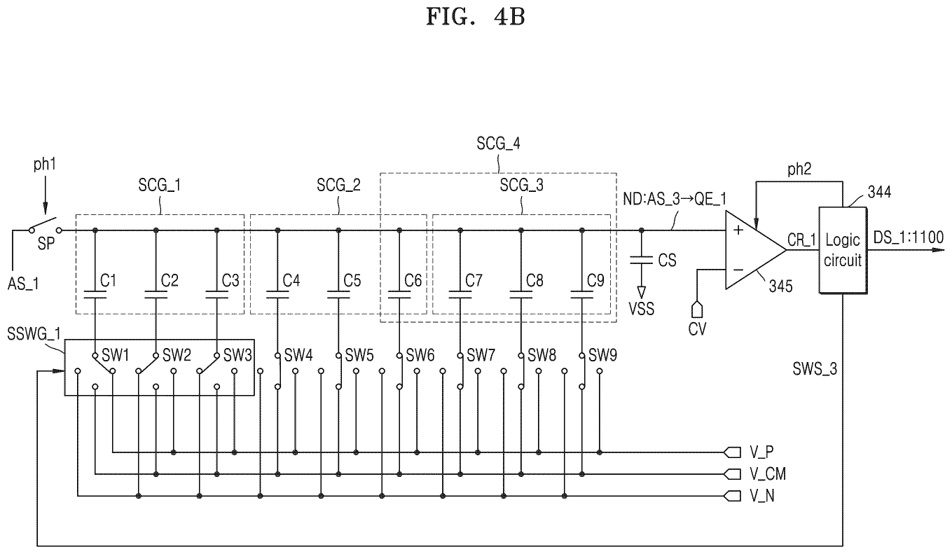

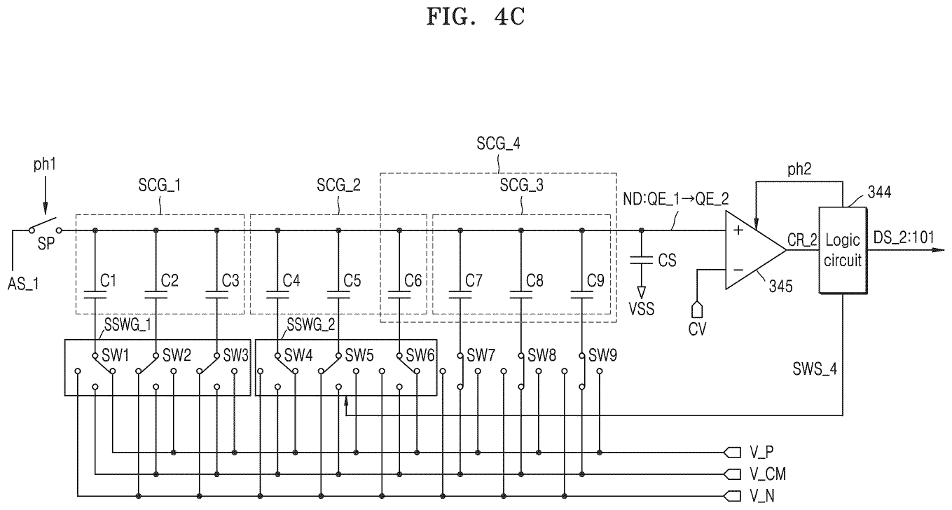

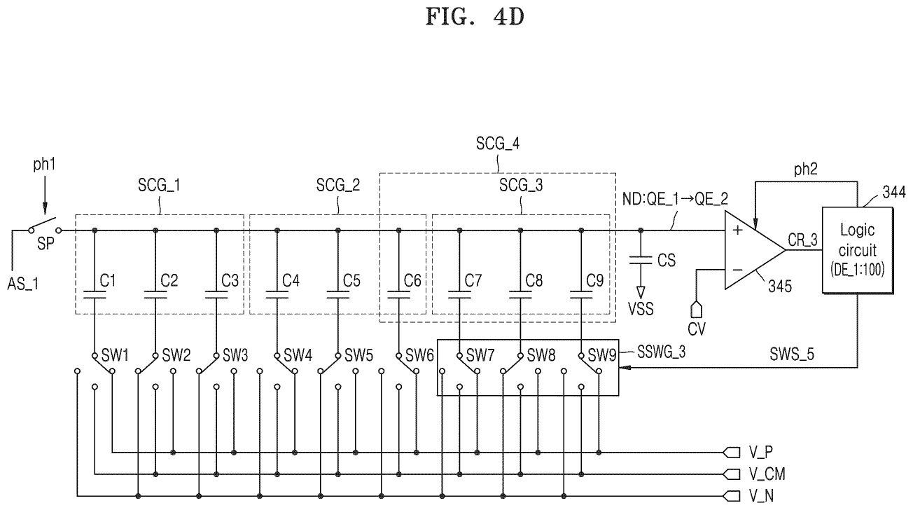

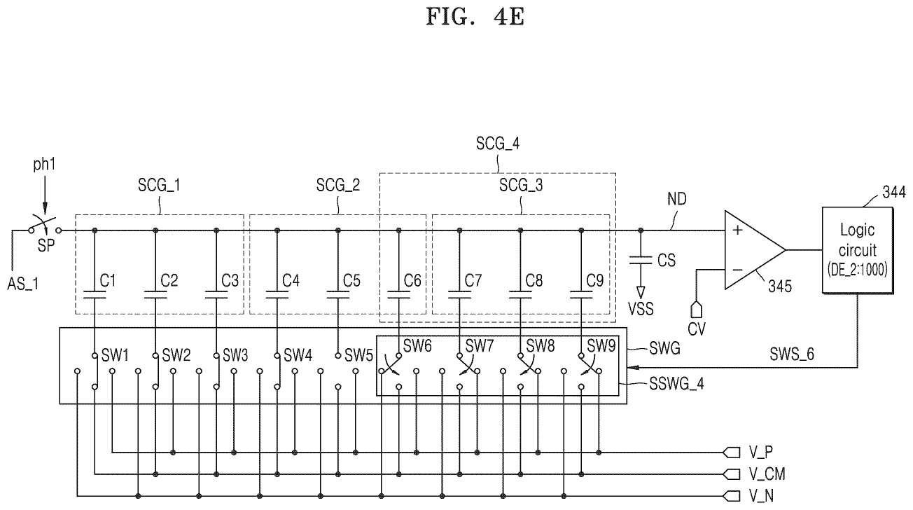

The capacitor group CG may include the plurality of capacitors C1 through C9. Each of the plurality of capacitors C1 through C9 may be connected to the reference node ND. In other words, the plurality of capacitors C1 through C9 may share the reference node ND. As described below with reference to FIG. 4A, the capacitor group CG may include a first sub capacitor group SCG_1, a second sub capacitor group SCG_2, a third sub capacitor group SCG_3, and a fourth sub capacitor group SCG_4. Each of the first sub capacitor group SCG_1, the second sub capacitor group SCG_2, the third sub capacitor group SCG_3, and the fourth sub capacitor group SCG_4 may include at least one capacitor. In addition, the third sub capacitor group SCG_3 and the fourth sub capacitor group SCG_4 may share at least one capacitor.

The plurality of capacitors C1 through C9 may have different capacitances. For example, the capacitance of a first capacitor C1 may be about 256 times the capacitance of the ninth capacitor C9, the capacitance of a second capacitor C2 may be about 128 times the capacitance of the ninth capacitor C9, the capacitance of a third capacitor C3 may be about 64 times the capacitance of the ninth capacitor C9, the capacitance of a fourth capacitor C4 may be about 32 times the capacitance of the ninth capacitor C9, the capacitance of a fifth capacitor C5 may be about 16 times the capacitance of the ninth capacitor C9, the capacitance of a sixth capacitor C6 may be about 8 times the capacitance of the ninth capacitor C9, the capacitance of a seventh capacitor C7 may be about 4 times the capacitance of the ninth capacitor C9, and the capacitance of the eighth capacitor C8 may be about 2 times the capacitance of the ninth capacitor C9.

The common capacitor CS may be connected between the reference node ND and a ground voltage VSS. Although, the common capacitor CS is illustrated as being connected to the ground voltage VSS in FIG. 3, the common capacitor CS may be connected between the reference node ND and a first reference voltage V_CM.

The switch group SWG may include the plurality of switches SW1 through SW9. The plurality of switches SW1 through SW9 included in the switch group SWG may respectively correspond to the plurality of capacitors C1 through C9 and may be respectively connected between the plurality of capacitors C1 through C9 and reference voltages V_P, V_CM, and V_N. In the present disclosure, a reference voltage may be used to include the first reference voltage V_CM, a second reference voltage V_P, and a third reference voltage V_N. Each of the plurality of switches SW1 through SW9 may be connected to any one of the first reference voltage V_CM, the second reference voltage V_P, and the third reference voltage V_N in response to the switch control signal SWS provided by the logic circuit 344. Each of the plurality of switches SW1 through SW9 may be connected to any one of the first reference voltage V_CM, the second reference voltage V_P, and the third reference voltage V_N, and accordingly, the voltage level of the reference node ND may be changed to preserve the amount of charge stored in each of the plurality of capacitors C1 through C9 and the common capacitor CS. In other words, the changed voltage level applied to the reference node ND may be based on the voltage level and a reference voltage applied to the reference node ND, and a charge amount stored in each of the plurality of capacitors. The converter (10 of FIG. 1) may generate the first digital signal DS_1, the second digital signal DS_2, and the first digital quantization signal DE_1, based on the changed voltage level of the reference node ND.

The logic circuit 344 may generate the sampling signal ph1, the comparator control signal ph2, and the switch control signal SWS.

The logic circuit 344 may provide the sampling signal ph1 to a sampler SP. As described above with reference to FIG. 1, the sampler SP may sample the first analog signal AS_1 based on the frequency (or the sampling ratio) of the sampling signal ph1. A voltage level corresponding to the sampled first analog signal AS_1 may be applied to the reference node ND.

In the SAR-ADC circuit of FIG. 3, as the sampling ratio increases, the SNR of the output signal Dout may be improved, but the power consumed for the sampling may increase. Accordingly, as described above, the converter (10 of FIG. 1) may include a loop filter of a lower order, the MASH structure, and the digital filter (400 in FIG. 1) to have the noise shaping effect of third-order or higher. Accordingly, the SNR of the output signal Dout may be improved.

The logic circuit 344 may provide the comparator control signal ph2 to the comparator 345. The comparator 345 may compare levels of voltages received at an inverting terminal and a non-inverting terminal based on the comparator control signal ph2. Referring to FIG. 3, the comparator 345 may compare a voltage level applied to the reference node ND received at the non-inverting terminal with a voltage level of a comparison voltage CV received at the inverting terminal based on the comparator control signal ph2. For example, the comparison voltage CV may be the same as the first reference voltage V_CM. The comparator 345 may compare levels of voltages received at the inverting terminal and the non-inverting terminal based on the comparator control signal ph2 and may generate a comparison result CR. For example, when the voltage level of the reference node ND received at the non-inverting terminal is greater than the voltage level of the comparison voltage CV received at the non-inverting terminal, the comparator 345 may provide the corresponding comparison result CR to the logic circuit 344. The logic circuit 344 may generate comparison data of “1” based on the comparison result CR. On the other hand, when the voltage level of the reference node ND received at the non-inverting terminal is less than the voltage level of the comparison voltage CV received at the non-inverting terminal, the comparator 345 may provide the corresponding comparison result CR to the logic circuit 344. The logic circuit 344 may generate comparison data of “0” based on the comparison result CR.

The logic circuit 344 may generate the switch control signal SWS based on the comparison data (“1” or “0”). Each of the plurality of switches SW1 through SW9 may be connected to any one of the second reference voltage V_P and the third reference voltage V_N based on the switch control signal SWS. The second reference voltage V_P may correspond to the comparison data of “1”, and the third reference voltage V_N may correspond to the comparison data of “0”. The first reference voltage V_CM may not correspond to the comparison data.

Detailed descriptions of operations of the main ADC 300b described above are provided with reference to FIGS. 4A through 4E to be described below.

FIGS. 4A, 4B, 4C, 4D, and 4E are circuit diagrams of operations of an example of the main ADC 300a.

Operations of the main ADC 300a of FIG. 3 are described below with reference to FIGS. 4A through 4E. FIGS. 4A through 4E may be described with reference to the descriptions given above with reference to FIGS. 1 through 3, and duplication descriptions thereof are omitted.

The operations of the main ADC 300a to be described below with reference to FIGS. 4A through 4E, are according to implementations of the present disclosure, which is only for convenience of explanation, and the present disclosure is not limited thereto. For example, in FIG. 4A, the second digital quantization signal DE_2 may be described as “1011”, but the present disclosure is not limited thereto.

The first sub capacitor group SCG_1 may include the first through third capacitors C1 through C3, the second sub capacitor group SCG_2 may include the fourth through sixth capacitors C4 through C6, the third sub capacitor group SCG_3 may include the seventh through ninth capacitors C7 through C9, and the fourth sub capacitor group SCG_4 may include the sixth through ninth capacitors C6 through C9.

FIG. 4A is a diagram an operation of the second adder 310 described above with reference to FIG. 2. As described above, the second adder 310 may generate the third analog signal AS_3 corresponding to the difference between the first analog signal AS_1 and the second analog signal (AS_2 in FIG. 2). Referring to FIG. 4A, the second digital quantization signal DE_2 corresponding to the second analog signal (AS_2 in FIG. 2) generated in the previous feedback cycle may be “1011”. The logic circuit 344 may generate a first switch control signal SWS_1 corresponding to the second digital quantization signal DE_2. The plurality of switches SW6 through SW9, respectively connected to the plurality of capacitors C6 through C9, included in the fourth sub capacitor group SCG_4 may be connected to one of the second reference voltage V_P and the third reference voltage V_N in response to the first switch control signal SWS_1. Because the second digital quantization signal DE_2 is “1011”, the logic circuit 344 may generate the first switch control signal SWS_1 such that the sixth switch SW_6 is connected to the second reference voltage V_P, the seventh switch SW_7 is connected to the third reference voltage V_N, the eighth switch SW_8 is connected to the second reference voltage V_P, and the ninth switch SW_9 is connected to the second reference voltage V_P.

Thereafter, the logic circuit 344 may generate the sampling signal ph1 to the sampler SP such that a voltage level corresponding to the first analog signal AS_1 is applied to the reference node ND. The logic circuit 344 may not generate the sampling signal ph1 such that the sampler SP is turned off when the voltage level corresponding to the first analog signal AS_1 is applied to the reference node ND. Accordingly, the voltage level of the reference node ND may correspond to the first analog signal AS_1, and the voltage level corresponding to the first analog signal AS_1 may be no longer applied to the reference node ND. Thereafter, the logic circuit 344 may generate a second switch control signal SWS_2 and provide the second switch control signal SWS_2 to the sixth through ninth switches SW6 through SW9. The sixth through ninth switches SW6 through SW9 may be connected to the first reference voltage V_CM in response to the second switch control signal SWS_2. The voltage level corresponding to the first analog signal AS_1 applied to the reference node ND may be changed to the voltage level corresponding to the third analog signal AS_3 corresponding to the difference between the first analog signal AS_1 and the second analog signal (AS_2 in FIG. 2) as the sixth through ninth switches SW6 through SW9 are connected to the first reference voltage V_CM in response to the second switch control signal SWS_2.

FIG. 4B is a diagram an operation of the ADC_1 320 described above with reference to FIG. 2. As described above, the ADC_1 320 may generate the first digital signal DS_1 based on the third analog signal AS_3. Referring to FIG. 4B, the comparator 345 may compare the voltage level corresponding to the third analog signal AS_3 applied to the reference node ND with a level of the comparison voltage CV and may provide a first comparison result CR_1 corresponding to the comparison result to the logic circuit 344. The logic circuit 344 may generate “1” as the comparison data when the voltage level corresponding to the third analog signal AS_3 is higher than the level of the comparison voltage CV and may generate “0” as the comparison data when the voltage level corresponding to the third analog signal AS_3 is lower than the level of the comparison voltage CV. For example, referring to FIG. 4B, the voltage level corresponding to the third analog signal AS_3 may be higher than the level of the comparison voltage CV, and the logic circuit 344 may generate “1” as the comparison data.

The logic circuit 344 may provide a third switch control signal SWS_3 to the first switch SW1 in response to the comparison data described above. For example, when the comparison data is “1”, the first switch SW1 may be connected to the second reference voltage V_P, and when the comparison data is “0”, the first switch SW1 may be connected to the third reference voltage V_N. When the first switch SW1 switches from the first reference voltage V_CM to the second reference voltage V_P or the third reference voltage V_N, the voltage level applied to the reference node ND may be changed. In other words, because the amount of charge stored in the first through ninth capacitors C1 through C9 and the common capacitor CS needs to be preserved, the voltage level applied to the reference node ND may be changed. The comparator 345 may compare the changed voltage level with the level of the comparison voltage CV to generate the first comparison result CR_1. The logic circuit 344 may generate the comparison data based on the first comparison result CR_1. For example, referring to FIG. 4B, a voltage level changed from the voltage level corresponding to the third analog signal AS_3 may be higher than the level of the comparison voltage CV, and the logic circuit 344 may generate “1” as the comparison data.

The logic circuit 344 may generate four pieces of comparison data by repeating the process described above on the first through third capacitors C1 through C3 included in the first sub capacitor group SCG_1 and on the first through third switches SW1 through SW3 corresponding to the first through third capacitors C1 through C3. The logic circuit 344 may generate the first digital signal DS_1 represented by four bits based on the four pieces of comparison data. The operations of the first through third switches SW1 through SW3 illustrated in FIG. 4B and the first digital signal (represented as DS_1:1100) corresponding thereto may be understood by using the descriptions above.

After the first digital signal DS_1 represented by four bits is generated, the voltage level applied to the reference node ND may be a voltage level corresponding to the first quantization error QE_1. In other words, a voltage level corresponding to the difference between the third analog signal AS_3 and the first digital signal DS_1 may be applied to the reference node ND and may remain.

FIG. 4C is a diagram an operation of the ADC_2 330 described above with reference to FIG. 2. As described above, the ADC_2 330 may generate the second digital signal DS_2 based on the first quantization error QE_1 corresponding to the difference between the third analog signal AS_3 and the first digital signal DS_1. As described above with reference to FIG. 4B, the logic circuit 344 may generate the second digital signal DS_2 by using the fourth through sixth capacitors C4 through C6 included in the second sub capacitor group SCG_2 and the fourth through sixth switches SW4 through SW6 corresponding thereto. For example, the logic circuit 344 may generate the fourth switch control signal SWS_4 and the second digital signal DS_2 based on a second comparison result CR_2. Each of the fourth through sixth switches SW4 through SW6 may be connected to the second reference voltage V_P or the third reference voltage V_N in response to the fourth switch control signal SWS_4. The operations of the fourth through sixth switches SW4 through SW6 illustrated in FIG. 4B and the second digital signal (represented as DS_1:101) corresponding thereto may be understood by using the descriptions above.

After the second digital signal DS_2 represented by three bits is generated, the voltage level applied to the reference node ND may be a voltage level corresponding to the second quantization error QE_2. In other words, the voltage level corresponding to the difference between the first quantization error QE_1 and the second digital signal DS_2 may be applied to the reference node ND and may remain.

FIG. 4D is a diagram of an operation of the NC-ADC 340 described above with reference to FIG. 2. As described above, the NC-ADC 340 may generate the first digital quantization signal DE_1 based on the second quantization error QE_2 corresponding to the difference between the first quantization error QE_1 and the second digital signal DS_2. As described above with reference to FIG. 4B, the logic circuit 344 may generate the first digital quantization signal DE_1 by using the seventh through ninth capacitors C7 through C9 included in the third sub capacitor group SCG_3 and the seventh through ninth switches SW7 through SW9 respectively corresponding thereto. For example, the logic circuit 344 may generate the fifth switch control signal SWS_5 and the first digital quantization signal DE_1 based on a third comparison result CR_3. Each of the seventh through ninth switches SW7 through SW9 may be connected to the second reference voltage V_P or the third reference voltage V_N in response to the fifth switch control signal SWS_5. The operations of the seventh through ninth switches SW7 through SW9 illustrated in FIG. 4B and the first digital quantization signal (represented as DE_1:100) corresponding thereto may be understood by using the descriptions above.

After the first digital quantization signal DE_1 represented by three bits is generated, the voltage level applied to the reference node ND may be a voltage level corresponding to the third quantization error QE_3. In other words, the voltage level corresponding to the difference between the second quantization error QE_2 and the first digital quantization signal DE_1 may be applied to the reference node ND and may remain.

FIG. 4E is a diagram of an operation of the NC-DAC 350 described above with reference to FIG. 2. As described above, the NC-DAC 350 may generate the second analog signal AS_2 based on the second digital quantization signal DE_2 corresponding to the first digital quantization signal DE_1 and provide the second analog signal AS_2 to the second adder 310. Referring to FIG. 4E, the logic circuit 344 may control the first through ninth switches SW1 through SW9 to be connected to the first reference voltage V_CM by providing the switch control signal to the first through ninth switches SW1 through SW9. Thereafter, the logic circuit 344 may provide the sixth switch control signal SWS_6 corresponding to the second digital quantization signal DE_2 to the sixth through ninth switches SW6 through SW9. Each of the sixth through ninth switches SW6 through SW9 may be connected to the second reference voltage V_P or the third reference voltage V_N in response to the sixth switch control signal SWS_6. FIG. 4E may be understood as similar to FIG. 4A.

FIG. 5 is a diagram of an example of a digital filter 400a.

Referring to FIG. 5, the digital filter 400a may include a signal digital filter 410, a noise digital filter 420, and a third adder 430.

As described above, the digital filter 400a may receive the first digital signal DS_1 and the second digital signal DS_2 from the main ADC (300 in FIG. 1). The digital filter 400a may generate the output signal Dout, based on the first digital signal DS_1 and the second digital signal DS_2.

The signal digital filter 410 may receive the first digital signal DS_1 and filter the first digital signal DS_1 to generate a filtered first digital signal FDS_1. The signal digital filter 410 may filter the first digital signal DS_1 based on a signal transfer function STF. The signal transfer function STF may be “1”. Accordingly, the first digital signal DS_1 may be the same as the filtered first digital signal FDS_1. Accordingly, the signal digital filter 410 may provide the first digital signal DS_1 to the third adder 430. Hereinafter, the first digital signal DS_1 is described on the premise that the first digital signal DS_1 is the same as the filtered first digital signal FDS_1. However, the present disclosure is not limited thereto.

The noise digital filter 420 may receive the second digital signal DS_2, filter the second digital signal DS_2, and generate the filtered second digital signal FDS_2. The noise digital filter 420 may filter the second digital signal DS_2 based on a noise transfer function NTF. The noise transfer function NTF may be expressed as Formula 1. Thus, the noise digital filter 420 may delay the second digital signal DS_2 based on the noise transfer function NTF and generate the filtered second digital signal FDS_2.

$$NTF = 1 - {Z}^{- 1} \qquad [ Formula 1 ]$$

Formula 1 represents the noise transfer function in the Z-domain. Here, the Z-domain may refer to a Z-domain generally used in digital signal processing. Therefore, in Formula 1, the pole may be 0 and zero may be 1. However, the noise transfer function NTF according to the present invention is not limited to Formula 1.

The third adder 430 may receive the filtered first digital signal FDS_1 from the signal digital filter 410. The third adder 430 may receive the filtered second digital signal FDS_2 from the noise digital filter 420. The third adder 430 may generate the output signal Dout by adding the filtered first digital signal FDS_1 to the filtered second digital signal FDS_2.

$${V}_{X} = {STF}_{A} \cdot {V}_{IN} - {NTF}_{A} \cdot {H}_{DNC} \cdot QE\_ 2 + {NTF}_{A} \cdot {H}_{DNC} \cdot QE\_ 3 + {NTF}_{A} \cdot QE\_ 1 \qquad [ Formula 2 ]$$

In Formula 2, V_{X} may correspond to the first digital signal DS_1, STF_{A} may correspond to the signal transfer function STF of the loop filter (200 in FIG. 1), NTF_{A} may correspond to the noise transfer function NTF of the loop filter (200 in FIG. 1), V_{IN} may correspond to the input signal (Ain in FIG. 1), and H_{DNC} may correspond to a transfer function of the digital noise coupling filter (600 in FIG. 1). QE_1, QE_2, and QE_3 may mean components corresponding to the first quantization error (QE_1 in FIG. 2), the second quantization error (QE_2 in FIG. 2), and the third quantization error (QE_3 in FIG. 2), respectively.

$${V}_{OUT} = {V}_{X} + {NTF}_{D} \cdot ( - QE\_ 1 + QE\_ 2 ) \\ {V}_{OUT} = {STF}_{A} \cdot {V}_{IN} - {NTF}_{A} \cdot {H}_{DNC} \cdot QE\_ 2 + {NTF}_{A} \cdot {H}_{DNC} \cdot QE\_ 3 + {NTF}_{A} \cdot QE\_ 1 + {NTF}_{D} \cdot ( - QE\_ 1 + QE\_ 2 ) \qquad [ Formula 3 ]$$

In Formula 3, NTF_{D} may correspond to the noise transfer function NTF of the noise digital filter 420 and V_{OUT} may correspond to the output signal Dout. Referring to Formula 3, when the noise transfer functions NTF and NTF_{A} are the same, a component corresponding to the first quantization error QE_1 may be removed from the output signal Dout. Accordingly, to remove a component corresponding to the first quantization error QE_1 from the output signal Dout, the noise transfer function NTF may be determined based on the transfer function of the loop filter (200 in FIG. 1).

Referring to Formula 3, the output signal Dout may include components respectively corresponding to the second quantization error QE_2 and the third quantization error QE_3 but may not include a component corresponding to the first quantization error QE_1 that has the largest size among the first quantization error QE_1, the second quantization error QE_2, and the third quantization error QE_3. Accordingly, the converter (10 of FIG. 1) may generate the output signal Dout with improved SNR.

As described above, the converter (10 of FIG. 1) may generate the output signal Dout with the improved SNR by including the digital noise coupling filter (600 in FIG. 1) and an M-0 MASH structure including the digital filter 400a.

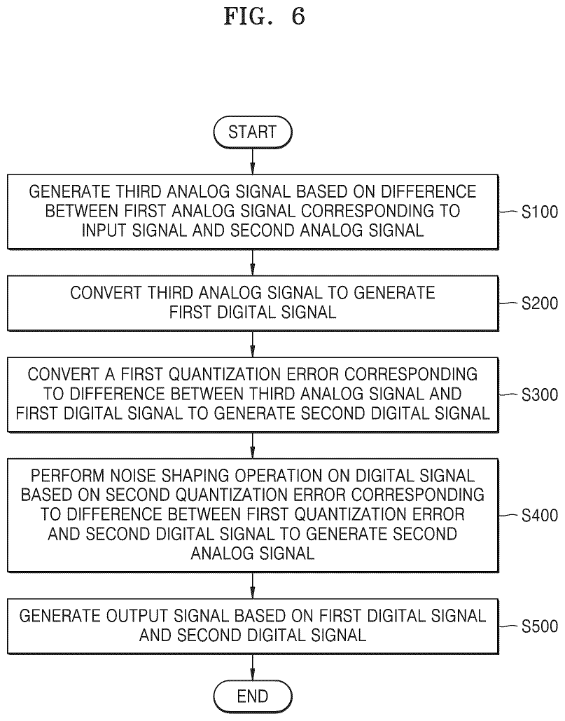

FIG. 6 is a flowchart of an example of an operation of the converter 10.

FIG. 6 may be described with reference to FIGS. 1 through 5, and duplicate descriptions thereof may be omitted.

Referring to FIG. 6, in operation S100, the converter (10 in FIG. 1) may generate a third analog signal based on the difference between a first analog signal and a second analog signal corresponding to an input signal.

In operation S200, the converter (10 in FIG. 1) may convert the third analog signal to generate a first digital signal.

In operation S300, the converter (10 in FIG. 1) may generate a second digital signal by converting a first quantization error corresponding to the difference between the third analog signal and the first digital signal.

In operation S400, the converter (10 in FIG. 1) may generate the second analog signal by performing a noise shaping operation on a second quantization error corresponding to the difference between the first quantization error and the second digital signal. The converter (10 in FIG. 1) may convert the second quantization error to generate a first digital quantization signal corresponding to the digital signal. The converter (10 in FIG. 1) may generate a second digital quantization signal by performing a noise shaping operation on the first digital quantization signal. The converter (10 in FIG. 1) may generate the second analog signal by converting the second digital quantization signal.

As described above, the size of the first quantization error may be greater than the size of the second quantization error.

In operation S500, the converter (10 in FIG. 1) may generate an output signal, based on the first digital signal and the second digital signal. The converter (10 in FIG. 1) may be a digital filter for removing the first quantization error for the MASH effect for improving the SNR described above, and may generate a filtered second digital signal by filtering the second digital signal based on a noise transfer function corresponding to the digital filter. The converter (10 in FIG. 1) may generate an output signal by adding the filtered second digital signal to the first digital signal. As described above, the converter (10 in FIG. 1) may generate the output signal which does not include a component corresponding to the first quantization error or the largest quantization error. Accordingly, the output signal generated by the converter (10 in FIG. 1) may have the SNR of the output signal improved.

The converter (10 in FIG. 1) may generate a differential signal based on the difference between an input signal and a feedback signal. The converter (10 in FIG. 1) may generate the first analog signal by filtering the differential signal based on the first transfer function corresponding to a low pass filter. In this case, the first transfer function may mean a transfer function of the loop filter described above with reference to FIG. 1. To remove the first quantization error from the output signal, the noise transfer function of the noise digital filter may be determined based on the first transfer function.

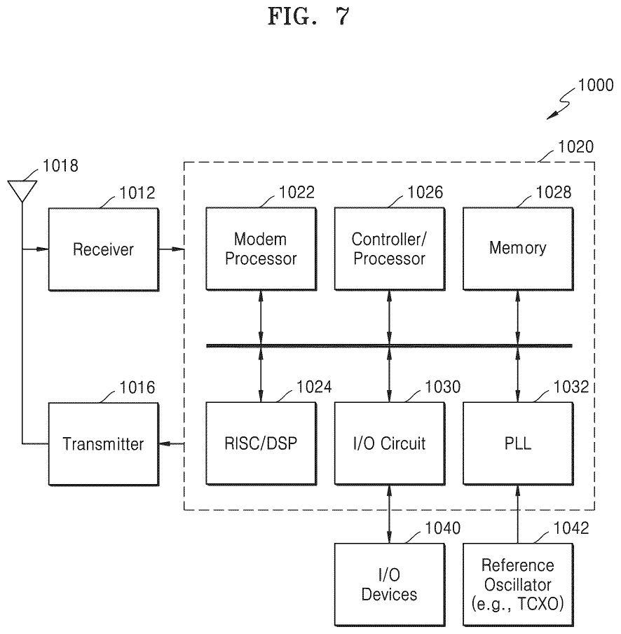

FIG. 7 is a block diagram of an example of a communication device 1000. FIG. 7 may be described with reference to FIG. 1, and thus, duplicate descriptions thereof may be omitted.

Referring to FIG. 7, the communication device 1000 may include a receiver 1012, a transmitter 1016, a communication module 1020, an antenna 1018, input/output (I/O) devices 1040, and a reference oscillator 1042. The receiver 1012 may include a converter 10 that provides a more precise output signal (Dout in FIG. 1), illustrated in FIG. 1. The receiver 1012 may convert an analog signal received via the antenna 1018 from the outside into a digital signal by using the converter 10 and then provide the digital signal to the communication module 1020. The transmitter 1016 may convert the digital signal received from the communication module 1020 into an analog signal and then output the analog signal to the outside via the antenna 1018.

The communication module 1020 may include a modem processor 1022, a reduced instruction set computer (RISC)/digital signal processor (DSP) (RISC/DSP) 1024, a controller/processor 1026, a memory 1028, an I/O device 1030, and a phase-locked loop (PLL) 1032.

The modem processor 1022 may perform processing operations, such as encoding, modulation, demodulation, and decoding, for data transmission and data receiving. The RISC/DSP 1024 may perform a general or specialized processing operation in the communication device 1000. The controller/processor 1026 may control blocks in the communication module 1020. The memory 1028 may store data and various command code. The I/O device 1030 may communicate with the I/O devices 1040 outside the I/O device 1030. The I/O device 1030 may convert a data signal received from the I/O devices 1040 outside the I/O device 1030 into a digital signal by using the converter 10 of FIG. 1. The PLL 1032 may perform a frequency modulation operation by using a frequency signal received from the reference oscillator 1042. The reference oscillator 1042 may be implemented as a crystal oscillator (XO), a voltage controlled crystal oscillator (VCXO), a temperature compensated crystal oscillator (TCXO), etc. The communication module 1020 may perform a processing operation necessary for communication by using output signals generated by the PLL 1032.

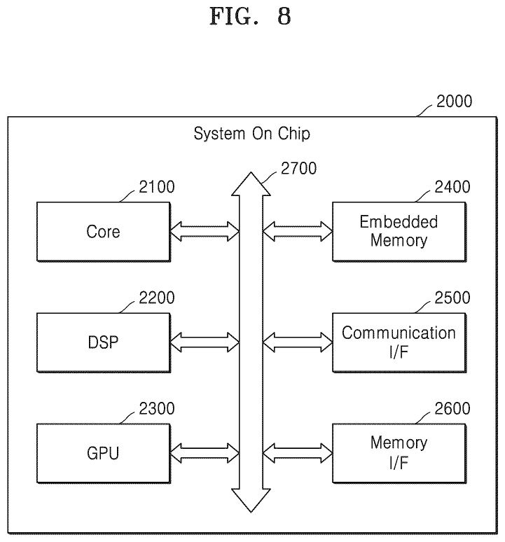

FIG. 8 is a block diagram of an example of a system-on-chip (SoC) 2000. FIG. 8 may be described with reference to FIG. 1, and duplicate descriptions thereof may be omitted.

Referring to FIG. 8, the SoC 2000 may be referred to as a computing system or an integrated circuit, in which components of another electronic system are integrated. For example, an application processor (AP), as one of the SoCs 2000, may include a processor and components for other functions.

The SoC 2000 may include a core 2100, a DSP) 2200, a graphics processing unit (GPU) 2300, an embedded memory 2400, a communication interface (I/F) 2500, and a memory I/F 2600. Components of the SoC 2000 may communicate with each other via a bus 2700.

The core 2100 may execute commands and control operations of components included in the SoC 2000. For example, the core 2100 may drive an operating system by executing a series of commands and execute applications on the operating system. The DSP 2200 may generate useful data by processing a digital signal, for example, a digital signal provided by the comm I/F 2500. The GPU 2300 may also generate data for an image output on a display device from image data provided by the embedded memory 2400 or the memory I/F 2600 and may also encode the image data. The embedded memory 2400 may store data necessary for operations of the core 2100, the DSP 2200, and the GPU 2300. The memory I/F 2600 may provide an I/F to external memories of the SoC 2000, for example, dynamic random access memory (RAM) (DRAM), flash memory, etc.

The comm I/F 2500 may provide serial communication with the outside of the SoC 2000. For example, the comm I/F 2500 may be connected to Ethernet and may include serializer/deserializer (SerDes) for serial communication.

On the other hand, the converter 10, to which implementations of the present disclosure are applied, may be applied to the comm I/F 2500 and the memory I/F 2600. By using the converter 10 providing the output signal (Dout in FIG. 1) with improved SNR, the comm I/F 2500 or the memory I/F 2600 may receive a data signal based on PAMn and convert the data signal into a digital data in manners according to the implementations of the present disclosure. In addition, the converter 10, to which the implementations of the present disclosure are applied, may be applied to applications requiring high resolution. For example, the converter 10 may be applied to audio reproducers and sensors.

The bus 2700 may operate based on one of various bus protocols. The various bus protocol may include at least one of advanced microcontroller bus architecture (AMBA) protocol, universal serial bus (USB) protocol, multi-media card (MMC) protocol, peripheral component interconnect (PCI) protocol, PCI-express (PCI-E) protocol, advanced technology attachment (ATA) protocol, serial-ATA protocol, parallel-ATA protocol, small computer system interface (SCSI) protocol, enhanced small disk interface (ESDI) protocol, integrated drive electronics (IDE) protocol, mobile industry processor interface (MIPI) protocol, and universal flash storage (UFS) protocol.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various change in form and details may be made therein without departing from the spirit and scope of the following claims.

What is claimed is:

1. A converter for converting an input signal into an output signal, the converter comprising:
a first adder configured to generate a differential analog signal, the differential analog signal corresponding to a difference between a first analog signal and a second analog signal, the first analog signal corresponding to the input signal;
a first analog-to-digital converter configured to convert the differential analog signal to a first digital signal;
a second analog-to-digital converter configured to convert a first quantization error to a second digital signal, the first quantization error corresponding to a difference between the differential analog signal and the first digital signal;
a digital noise coupling filter configured to generate a second digital quantization signal based on performing a noise shaping operation on a first digital quantization signal, the second digital quantization signal corresponding to the second analog signal, the first digital quantization signal corresponding to a second quantization error, and the second quantization error corresponding to a difference between the first quantization error and the second digital signal; and
a digital filter configured to, based on the first digital signal and the second digital signal, generate the output signal.

2. The converter of claim 1, wherein the digital filter comprises:
a noise digital filter configured to perform a filtering operation on the second digital signal to generate a filtered second digital signal; and
a second adder configured to add the filtered second digital signal to the first digital signal to generate the output signal.

3. The converter of claim 2, comprising:
a digital-to-analog converter configured to convert the first digital signal to a feedback signal;
a third adder configured to generate a differential signal based on a difference between the input signal and the feedback signal; and
a loop filter configured to perform a low pass filtering operation on the differential signal to generate the first analog signal.

4. The converter of claim 3, wherein a transfer function of the noise digital filter corresponds to a transfer function of the loop filter.

5. The converter of claim 1, comprising:
a noise coupling analog-to-digital converter configured to convert the second quantization error to the first digital quantization signal; and
a noise coupling digital-to-analog converter configured to convert the second digital quantization signal to the second analog signal.

6. The converter of claim 5, wherein
the noise coupling analog-to-digital converter is configured to generate a third quantization error, the third quantization error corresponding to a difference between the second quantization error and the first digital quantization signal.

7. The converter of claim 6, wherein the output signal comprises a component corresponding to the second quantization error and a component corresponding to the third quantization error.

8. The converter of claim 6, wherein
a size of the first quantization error is greater than a size of the second quantization error and a size of the third quantization error, and the size of the second quantization error is greater than the size of the third quantization error.

9. A method of converting an input signal into an output signal, the method comprising:
generating a differential analog signal based on a difference between a first analog signal and a second analog signal, the first analog signal corresponding to the input signal;
generating a first digital signal based on converting the differential analog signal;
generating a second digital signal based on converting a first quantization error, the first quantization error corresponding to a difference between the differential analog signal and the first digital signal;
generating the second analog signal based on performing a noise shaping operation on a digital signal, the digital signal corresponding to a second quantization error, the second quantization error corresponding to a difference between the first quantization error and the second quantization error; and
generating, based on the first digital signal and the second digital signal, the output signal.

10. The method of claim 9, wherein generating the second analog signal comprises:
generating a first digital quantization signal based on converting the second quantization error, the first digital quantization signal corresponding to the digital signal;
generating a second digital quantization signal based on performing a noise shaping operation on the first digital quantization signal; and
generating the second analog signal based on converting the second digital quantization signal.

11. The method of claim 9, wherein a size of the first quantization error is greater than a size of the second quantization error.

12. The method of claim 9, wherein generating the output signal comprises:
generating a filtered second digital signal based on filtering the second digital signal, wherein filtering the second digital signal is based on a noise transfer function; and
generating the output signal based on adding the filtered second digital signal to the first digital signal.

13. The method of claim 12, comprising:
generating a feedback signal based on converting the first digital signal;
generating a differential signal based on a difference between the input signal and the feedback signal; and
generating the first analog signal based on filtering the differential signal, wherein filtering the differential signal is based on a first transfer function, the first transfer function corresponding to a low pass filter,
wherein the noise transfer function is determined based on the first transfer function.

14. A converter for converting an input signal into an output signal, the converter comprising:
a first adder configured to generate a differential signal based on a difference between the input signal and a feedback signal;
a loop filter configured to perform, based on a first transfer function, a filtering operation on the differential signal to generate a first analog signal, the first transfer function corresponding to a low pass filter;
a main analog-to-digital converter configured to convert the first analog signal to a first digital signal and a second digital signal;
a digital-to-analog converter configured to convert the first digital signal to a feedback signal, the feedback signal to be fed back to the first adder; and
a digital filter configured to generate, based on the first digital signal and the second digital signal, the output signal,
wherein the main analog-to-digital converter is configured to
generate a differential analog signal, the differential analog signal corresponding to a difference between the first analog signal and a second analog signal,
convert the differential analog signal to a first digital signal, and
convert a first quantization error to the second digital signal, the first quantization error corresponding to a difference between the differential analog signal and the first digital signal.

15. The converter of claim 14, wherein the digital filter is configured to
perform, based on a noise transfer function corresponding to the first transfer function, a filtering operation on the second digital signal to generate a filtered second digital signal, and
add the filtered second digital signal to the first digital signal to generate the output signal.

16. The converter of claim 14, comprising:
a digital noise coupling filter configured to perform a noise shaping operation on a first digital quantization signal to generate a second digital quantization signal, the first digital quantization signal corresponding to a difference between the first quantization error and the second digital signal
wherein the main analog-to-digital converter is configured to
convert a second quantization error to the first digital quantization signal, the second quantization error corresponding to the difference between the first quantization error and the second digital signal, and
convert the second digital quantization signal to the second analog signal.

17. The converter of claim 14, wherein the main analog-to-digital converter comprises:
a capacitor group including a plurality of capacitors, the plurality of capacitors sharing a reference node to which a voltage level is applied, the voltage level corresponding to an analog signal;
a plurality of switches connected between each capacitor of the plurality of capacitors and a reference voltage;
a comparator configured to compare the voltage level with a level of a comparison voltage to generate a comparison result; and
a logic circuit configured to
generate, based on the comparison result, a switch control signal, the switch control signal configured to control the plurality of switches respectively corresponding to the plurality of capacitors, and
generate, based on the comparison result, the first digital signal and the second digital signal.

18. The converter of claim 17, wherein
the reference voltage comprises a first reference voltage corresponding to a comparison voltage, a second reference voltage higher than the first reference voltage, and a third reference voltage lower than the first reference voltage, and
wherein each capacitor of the plurality of capacitors is configured to be connected to one of the first reference voltage, the second reference voltage, and the third reference voltage based on the switch control signal.

19. The converter of claim 18, wherein
the capacitor group comprises a first sub capacitor group, the first sub capacitor group including the plurality of capacitors,
wherein the comparator is configured to compare a first voltage level applied to the reference node and the level of the comparison voltage to generate a first comparison result, and the first voltage level is based on an amount of charge stored in each capacitor of the plurality of capacitors, and
wherein the logic circuit is configured to generate, based on the first comparison result, the second digital signal and a first switch control signal, the first switch control signal configured to control a plurality of switches respectively connected to the plurality of capacitors.

20. The converter of claim 19, wherein
the capacitor group comprises a second sub capacitor group, the second sub capacitor group including the plurality of capacitors,
wherein the comparator is configured to
compare a second voltage level applied to the reference node and the level of the comparison voltage to generate a second comparison result, and the second voltage level is based on a charge amount stored in each capacitor of the plurality of capacitors,
wherein the logic circuit is configured to generate, based on the second comparison result, a first digital quantization signal and a second switch control signal, the second switch control signal configured to control the plurality of switches.
